(19) United States
(12) Patent Application Publication
(10) Pub. No.: US 2018/0247800 A1
(43) Pub. Date: Aug. 30, 2018

(54) GALLIUM IMPLANTATION CLEANING METHOD

(71) Applicant: INTERNATIONAL BUSINESS MACHINES CORPORATION, Armonk, NY (US)

(72) Inventors: Oleg Gluschenkov, Tannersville, NY (US); Alexandru F. Petrescu, Albany, NY (US); Robert R. Young, JR., Albany, NY (US)

(21) Appl. No.: 15/445,372

(22) Filed: Feb. 28, 2017

(51) Int. Cl. H01J 37/36; H01L 21/265; H01J 37/317; B08B 5/00; B08B 7/04; B08B 7/00; C23C 14/48; C23C 14/14

(52) U.S. Cl. CPC H01J 37/36; H01L 21/265; H01J 37/3171; B08B 5/00; B08B 7/04; H01J 2237/31705; C23C 14/48; C23C 14/14; H01L 21/26506; H01J 2237/022; H01J 2237/335; B08B 7/0035

(57) ABSTRACT

A method is presented for cleaning an ion implanter during operation of the ion implanter. The method includes generating a gallium (III) iodide (GaI₃) vapor from a GaI₃ source running concurrently with a hydrogen-containing gaseous plasma to cause a reaction with at least iodine (I) residue deposits, selectively filtering ions from the GaI₃ vapor and the hydrogen-containing gaseous plasms to create a Ga ion beam, and directing the Ga ion beam onto a semiconductor substrate for Ga implantation. After completion of the Ga implantation, an argon (Ar) based ion beam is run through the ion implanter for post-cleaning of the ion implanter.

### BACKGROUND

### Technical Field

The present invention relates generally to semiconductor devices, and more specifically, to a gallium (Ga) implantation cleaning method.

### Description of the Related Art

An ion implantation is a standard technique for introducing conductivity-altering impurities into workpieces such as semiconductor wafers. In a beamline ion implanter, there is an ion source region that includes an ion source that generates an ion beam and extraction electrodes that extract the beam from the ion source. A beamline region manipulates the energy and shape of the ion beam. A process chamber region, which contains a workpiece, receives the ion beam from the beamline region. The ion beam impacts the workpiece, thus causing the ions in the beam to penetrate the surface of the workpiece coming to rest beneath the surface to form a region of desired conductivity.

### SUMMARY

In accordance with an embodiment, a method is provided for cleaning an ion implanter during operation of the ion implanter. The method includes generating metallic ion species from an ion source, running a hydrogen-containing gaseous plasma concurrently with the metallic ion species to cause a reaction with at least one contaminant within the ion implanter, selectively filtering ions from the metallic ion species and the hydrogen-containing gaseous plasma to create an ion beam, and directing the ion beam onto a semiconductor substrate for implantation of a dopant.

In accordance with another embodiment, a method is provided for cleaning an ion implanter. The method includes generating a gallium (III) iodide (GaI₃) vapor from a GaI₃ source running concurrently with a hydrogen-containing gaseous plasma to cause a reaction with at least iodine (I) residue deposits, selectively filtering ions from the GaI₃ vapor and the hydrogen-containing gaseous plasms to create a Ga ion beam, and directing the Ga ion beam onto a semiconductor substrate for Ga implantation.

In accordance with another embodiment, a system is provided for cleaning an ion implanter during operation of the ion implanter. The system includes an ion source for generating metallic ion species, the ion source run concurrently with a hydrogen-containing gaseous plasma to cause a reaction with at least one contaminant within the ion implanter; and a filter for selectively filtering ions from the metallic ion species and the hydrogen-containing gaseous plasma to create an ion beam. The ion beam is directed onto a semiconductor substrate for implantation of a dopant.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE SEVERAL VIEWS OF THE DRAWINGS

The invention will provide details in the following description of preferred embodiments with reference to the following figures wherein:

FIG. 1 is a perspective view of an ion implanter including an ion source where appropriate metallic ion species are generated, in accordance with an embodiment of the present invention;

FIG. 2 is a block/flow diagram of an exemplary method for implanting a dopant into a semiconductor substrate, in accordance with an embodiment of the present invention;

FIG. 3 is a block/flow diagram of an exemplary method for removing gallium (Ga) and iodine (I) contaminants from surfaces of an ion implanter, in accordance with an embodiment of the present invention;

FIG. 4 is a block/flow diagram of an exemplary method for utilizing consecutive ion implantations sequences including implantation of gallium (Ga) ions followed by implantation of different ions, in accordance with an embodiment of the present invention; and

FIG. 5 is an exemplary graph depicting experimental data showing improvements in levels of Ga and I contamination utilizing cleaning methods, in accordance with an embodiment of the present invention.

Throughout the drawings, same or similar reference numerals represent the same or similar elements.

### DETAILED DESCRIPTION

Embodiments of the present invention relate to ion implanters. Ion implanters process ions by accelerating them in an electric field to be impacted onto a solid. The solid can be, e.g., a semiconductor wafer. Ion implanters can include a number of different ion sources. One useful example of such an ion source can be a gallium (III) iodide (GaI₃) source. The ions implanted onto the solid can be a variety of different dopants or doping agents. Dopants can be selected from, e.g., group III elements or group V elements. One such useful dopant can be, e.g., gallium (Ga). The ion implanter can create a Ga ion beam to be directed into a semiconductor wafer, such as a silicon (Si) wafer. However, as the ions travel through the ion implanter, residue deposits or contaminants can be left behind. These contaminants need to be removed from various sections of the ion implanter. Removal of such contaminants can be accomplished by cleaning methods described herein.

The exemplary embodiments of the present invention provide cleaning methods performed at two different stages. A first cleaning method can be performed during normal operation of the ion implanter (e.g., during Ga implantation into a wafer). In such case, a carrier gas is employed concurrently with the gallium (III) iodide (GaI₃) vapor produced by the GaI₃ source. A second cleaning method can be performed after completion of an ion implantation procedure (e.g., after implantation of Ga into a wafer). In such case, a cleaning gas is used, for example, including argon (Ar).

In one or more embodiments, during normal operation, an Ar/H₂ (argon/hydrogen gas) or an AsH₃ (arsine) gas is used as a carrier gas or co-gas or co-process gas during Ga implantation (first cleaning method), thus providing the source of hydrogen for a hydrogen-containing gaseous plasma in the ion source of the ion implanter. The carrier gas is run concurrently with the source of desired ions, the components of the carrier gas are ionized and extracted, but only desired ions are filtered and implanted into a wafer.

In one or more embodiments, a cleaning gas can be used to post-clean the ion implanter after Ga implantation has been completed (second cleaning method). The cleaning gas, following completion of Ga implantation, reduces contamination when the wafer is removed from the vacuum chamber of the ion implanter. The cleaning gas is run through the operating ion source, the cleaning gas components are ionized and extracted, and one of its ionic constituents is filtered and propagated through at least the beamline region for beamline cleaning purposes. In one example embodiment, 3.9% H₂ in Ar gas is used as a cleaning gas instead of pure Ar, as conventionally used. The presence of molecular hydrogen gas (H₂) and atomic hydrogen (H) produced in the ion source plasma from hydrogen molecules volatilizes the iodine (I) that normally coats the ion source chamber and can even propagate and contaminate surfaces of the beamline region after excessive use. Volatile hydrogen iodine (HI) molecules are then pumped out by the existing pumping system.

In one or more embodiments, during post-cleaning of the ion implanter, argon ions (Ar+) help evaporate and sputter any gallium (Ga) deposited on the ion source chamber and the surfaces of the beamline region. Ga atoms cannot be easily volatilized by reacting with either hydrogen or halogens (e.g., fluorine, chlorine), instead, they can be evaporated with the help of an external energy source or heat. Energetic Ar ions provide the external energy source for promoting efficient evaporation and sputtering of deposited Ga atoms. The efficiency of surface sputtering increases with the size (atomic number or mass) of impinging ions. Accordingly, ionized noble gases with a larger atomic number, such as Ne+, Ar+, Kr+, and Xe+ are preferred. Due to its abundance and widespread use, ionized argon Ar+ is mostly preferred.

In one or more embodiments, during post-cleaning of the ion implanter, Ar/H₂ (argon/hydrogen gas) is used as a cleaning gas for simultaneous cleaning of iodine (I) and gallium (Ga) in the ion source and in the beamline region. While the ion source is operated to continuously produce argon ions, atomic hydrogen, and hydrogen ions, the ion filtering magnet is adjusted to filter either Ar+ ion or hydrogen ion H+ and propagate selected ions through the beamline region for cleaning purposes. Running the Ar+ ion through the beamline region for about 15 minutes is sufficient to reduce contamination. Running an additional H+ cycle through the beamline region is optional and preferred in cases where, for example, severe iodine contamination is present. This H+ beamline cleaning cycle is conducted after the initial Ar+ cleaning cycle and is followed by an additional Ar+ ion cleaning cycle to sputter any deposits induced or disturbed by the presence of hydrogen in the beamline region. Advantageously, these cleaning cycles are conducted without a workpiece/wafer present in the ion implanter. This reduces or eliminates the use of a dedicated workpiece/wafer, known as gettering wafers, that is employed for running dummy implantation steps to getter contaminants by gettering wafers.

In one or more embodiments, during post-cleaning of the ion implanter, an Ar/H₂ gas is used with 3.9% H₂ in Ar as a non-flammable hydrogen mixture, and, thus, there is no need for providing additional sensors/safety measures.

In one or more embodiments, during normal operation of the ion implanter, an Ar/H₂ (argon/hydrogen) gas mixture is used as a carrier gas or co-gas or co-process gas during Ga implantation. Unlike other hydrogen sources, the Ar/H₂ mixture does not interact with the hot crucible vaporizing the solid GaI₃ and is free of other dopants, such as phosphorus (P) or arsenic (As). Even though, the ions of unwanted dopants are filtered by the magnet, their volatile neutrals can propagate through the beamline region and contaminate the workpiece/wafer surface with the wrong type of dopant. The Ar/H₂ gaseous mixture is readily available and relatively inexpensive. Due to its non-flammable property, Ar/H₂ gas with 3.9% H₂ in Ar is advantageous. Higher concentration of hydrogen in the mixture raises safety concerns around a heated crucible and hydrogen alone would do little to control Ga contamination. However, the Ar/H₂ gas can eliminate such deficiencies during the normal operation of the ion implanter.

As used herein, “semiconductor device” refers to an intrinsic semiconductor material that has been doped, that is, into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. Dominant carrier concentration in an extrinsic semiconductor determines the conductivity type of the semiconductor.

A “gate structure” means a structure used to control output current (i.e., flow of carriers in the channel) of a semiconducting device through electrical or magnetic fields.

As used herein, the term “drain” means a doped region in the semiconductor device located at the end of the channel, in which carriers are flowing out of the transistor through the drain.

As used herein, the term “source” is a doped region in the semiconductor device, in which majority carriers are flowing into the channel.

The term “direct contact” or “directly on” means that a first element, such as a first structure, and a second element, such as a second structure, are connected without any intermediary conducting, insulating or semiconductor layers at the interface of the two elements.

The terms “over,” “overlying,” “atop,” “positioned on” or “positioned atop” means that a first element, such as a first structure, is present on a second element, such as a second structure, wherein intervening elements, such as an interface structure can be present between the first element and the second element.

The term “electrically connected” means either directly electrically connected, or indirectly electrically connected, such that intervening elements are present; in an indirect electrical connection, the intervening elements can include inductors and/or transformers.

The term “crystalline material” means any material that is single-crystalline, multi-crystalline, or polycrystalline.

The term “non-crystalline material” means any material that is not crystalline; including any material that is amorphous, nano-crystalline, or micro-crystalline.

The term “intrinsic material” means a semiconductor material which is substantially free of doping atoms, or in which the concentration of dopant atoms is less than 10¹⁵ atoms/cm³.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As used herein, an “anisotropic etch process” denotes a material removal process in which the etch rate in the direction normal to the surface to be etched is greater than in the direction parallel to the surface to be etched. The anisotropic etch can include reactive-ion etching (RIE). Other examples of anisotropic etching that can be used include ion beam etching, plasma etching or laser ablation.

RIE is a form of plasma etching in which during etching the surface to be etched is placed on the RF powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

The term “processing” as used herein includes deposition of material or photoresist, patterning, exposure, development, etching, cleaning, stripping, implanting, doping, stressing, layering, and/or removal of the material or photoresist as required in forming a described structure.

As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The terms “gas” and “gases” are used interchangeably, unless otherwise noted, and refer to one or more precursors, reactants, catalysts, carrier, purge, cleaning, combinations thereof, as well as any other fluid introduced into the chamber body.

As used herein, “ion source region” includes the vacuum chamber, the source arc chamber, the source insulators, the extraction electrodes, the suppression electrodes, the high voltage insulators and the source bushing.

As used herein, the “residue” may comprise, consist essentially of or consist of at least silicon, boron, phosphorus, germanium, iodine, gallium and/or arsenic.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this invention.

The present subject matter will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

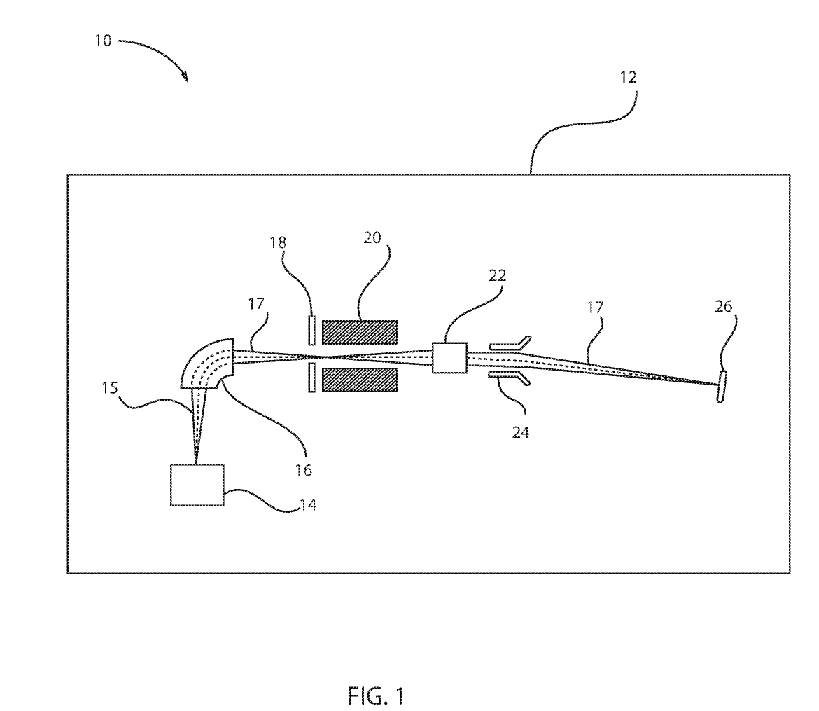

FIG. 1 is a perspective view of an ion implanter including an ion source where appropriate metallic ion species are generated, in accordance with an embodiment of the present invention.

The ion implanter 10 can have multiple components, such as an ion source 14 where appropriate metallic ion species 15 are generated, an analyzer magnet 16, which removes or filters unwanted ions, an ion beam accelerator column 20, which gives the selected metallic ion species 17 their energy, the selected metallic ions 17 passed through a variable slit 18 for beam control, vertical and horizontal scanning electrodes 22, which can deflect and shape the ion beam 17 electrostatically, and a target 26, which secures the wafer. The ion beam can raster or scan across the wafer utilizing scanning electrodes 22, 24 or, alternatively, the movable target 26 can scan the wafer under a stationary beam. The whole unit is housed inside a large vacuum chamber 12 and wafers are transferred into and from the implanter 10 one at a time.

The exemplary embodiments of the present invention relate to cleaning during implantation and after implantation of metallic ion species 15. The metallic ion species 15 cannot be volatized by pure hydrogen (H). Examples of such metallic ion species 15 include, but are not limited to, aluminum (Al), gallium (Ga), and indium (In). Such metallic ion species 15 contaminating the ion implanter 10 can be cleaned by applying hydrogen with another element (e.g., Ar, As, etc.)

Several types of ion sources 14 can be employed to generate metallic ion species 15 in commercial ion implantation systems, including, e.g., Freeman and Bernas ion sources using thermoelectrodes and powered by an electric arc, a microwave type using a magnetron, indirectly heated cathode sources, and radio-frequency (RF) plasma sources, all of which can operate in a vacuum. The ion source 14 generates ions by introducing electrons into a vacuum chamber filled with the dopant gas (commonly referred to as the “feedstock gas”). Collisions of the electrons with dopant atoms and molecules in the gas results in the creation of an ionized plasma including positive and negative dopant ions. An extraction electrode with a negative or positive bias will respectively permit the positive or negative ions to pass through the aperture and out of the ion source as a collimated ion beam, which is then filtered in accordance with their charge-to-mass ratio by the analyzer magnet 16 and accelerated towards the workpiece/wafer 26. The partial pressure inside the plasma source 14 can be higher than that in the beamline section and the process chamber. The partial pressure in the plasma source 14 is selected to sustain the optimum plasma condition of the source and can be from about 10⁻⁵ Torr to 10⁻⁴ Torr. The partial pressure in the beamline section and the process chamber is selected to prevent excessive collisions between ions and neutrals, and can be from about 10⁻⁷ Torr to about 10⁻⁶ Torr. Despite effective differential pumping of these sections, this difference in pressure can result in the unwanted drift of volatile neutrals through the beamline into the process chamber leading to residual contamination of the wafer surface. Contamination of wafer surface by undesirable species is preferably kept to a minimum and below about 10¹² atoms/cm².

In one embodiment, the ion implantation system can further comprise processor and controller components (not shown), on board or off board, for controlling the delivery rate, duration, temperature, pressure and composition of the cleaning agent, being flowed through the flow circuitry to the ion implanter 10 or component thereof undergoing cleaning.

The processor and controller components can include components associated with the flow circuitry, such as flow control valves, back pressure valves, flow control orifice elements, mass flow controllers, pressure regulators, pressure sensors, temperature monitoring devices, cleaning agent analyzers, flow monitors, flow totalizers, heating components such as heat exchange tracing of flow circuitry lines, heat exchanger passages integrated with the flow circuitry lines, or other components for monitoring, analysis, or control of the cleaning agent or process variables associated therewith. Processor components can include microprocessors, programmable logic components, central processing units (CPUs), special-purpose programmed computers, general-purpose programmed computers are arranged to execute software effectuating cleaning operations, and the like, with associated displays, data outputs, wireless transmitters, and the like, whereby graphical or digital outputs can be generated and transmitted for viewing and/or use.

Ion implantation is a lower temperature process than doping by thermal diffusion in which precise numbers of impurity atoms are implanted into a wafer from a high energy ion beam. The ions enter the semiconductor with high velocity and dissipate their energy through a series of collisions and also get neutralized. In the process, the ions travel a distance R, called the range, which is larger than the perpendicular distance penetrated below the surface of the wafer before coming to rest. The median perpendicular penetration depth, called the projected range Rₚ, depends on the energy of the incident ion on impact with the wafer. Since the collisions are random, there will be a range of depths over which the ions are distributed varying predominately from its median value Rₚ to Rₚ+ΔRₚ, where ΔRₚ is called the projected straggle. Also, there is some scattering of the ions in the direction normal to the axis of incidence as they penetrate into the semiconductor wafer. This lateral spread is measured by the lateral projected range R_{⊥} and its straggle ΔR_{⊥}. Larger ions have smaller ΔRₚ and ΔR_{⊥} resulting in a more precise geometrical placement of implanted impurities. This provides a significant advantage in geometrically-scaled semiconductor devices where the source or drain separated from the gate structure by less than the value of (R_{⊥}+3ΔR_{⊥}) for the lighter ion. It is this advantage of precise impurity placement that is a factor behind shifting from a lighter boron (B) ion to a heavier gallium ion for implanting p-type impurity. By way of example, 2 keV Ga ion implantation has Rₚ of 4 nm, ΔRₚ of 1.9 nm, R_{⊥} of 1.4 nm, and ΔR_{⊥} of 1.7 nm in Si_{0.5}Ge_{0.5} source or drain material, while Rₚ-equivalent boron implantation at 550 eV has Rₚ of 4 nm, ΔRₚ of 2.3 nm, R_{⊥} of 2.2 nm, and ΔR_{⊥} of 2.8 nm. Accordingly, Ga implantation enables source/drain and gate structure separation down to about 6 nm, while the equivalent B implantation limits this separation distance to above about 10 nm.

An ion implantation is one technique for introducing conductivity-altering or other impurities into workpieces such as semiconductor wafers. In a beamline ion implanter, an ion source region can include an ion source that generates an ion beam and extraction electrodes that extract the beam from the ion source. A beamline region manipulates the energy and shape of the ion beam. A process chamber region, which includes a workpiece, receives the ion beam from the beamline region. The ion beam contacts the workpiece, causing the ions in the beam to penetrate the surface of the workpiece coming to rest beneath the surface, forming a region of desired conductivity or altering chemical composition of material.

Each ion implantation leaves behind residual deposits in the ion source region, beamline region, and process chamber region of the ion implanter. The residual deposits include solid residue deposits of the nonvolatile species used in the ion implantation such as arsenic (As), phosphorus (P), boron (B), iodine (I), and/or gallium (Ga). The solid residue deposits can result in a multitude of operational issues in the ion source region, beamline region, and process chamber region. For instance, these deposits can cause electrical short circuits, premature failure, and damage to equipment. To prevent these issues, operators of the ion implanter routinely clean the residual deposits from the ion source region, beamline region, and process chamber region. In addition, the deposits can be volatilized in subsequent implantation steps causing wafer surface contamination in excess of about 10¹² atoms/cm². Because the residual deposits left behind in the ion source region, beamline region, and process chamber region can be also volatilized during cleaning, there can be health risks for personnel assigned to clean these regions of the ion implanter. As a result, an ion implanter cleaning process should be able to remove solid residue deposits from the ion source region, beamline region, and process chamber region while protecting personnel from the harmful effects of vapors from these deposits.

A conventional cleaning process of an ion implanter begins by first shutting down the ion implanter. A gas is introduced to the ion implanter to vent the system to atmospheric pressure and then the implanter is exhausted for a predetermined time to remove toxic contaminants from the implanter. Cleaning personnel then enter the ion implanter wearing protective clothing and a self-contained breathing apparatus and begin cleaning the ion source region, beamline region and process chamber region by hand. In particular, the cleaning personnel disassemble various components in the ion source region, beamline region and process chamber region and scrub these components with a cleaning solution that can include a combination of hydrogen peroxide (H₂O₂), alcohol and water. The cleaning personnel aggressively scrub the components in order to thoroughly clean them. The cleaning personnel have to be careful while scrubbing the components because solid residue deposits of species such as phosphorous (P) can react with the cleaning solution and cause a flash fire. The hand cleaning of components can take anywhere from about four to six hours. After the hand cleaning, the components are reassembled and then a high vacuum is formed in the ion implanter. Vapors from the cleaning solution used to clean the ion implanter are then outgassed as well as other particles that are byproducts of the scrubbing. This outgassing of vapors can take, e.g., another 12 hours.

The exemplary embodiments of the present invention provide cleaning methods performed at two different stages. A first cleaning method can be performed during normal operation of the ion implanter (e.g., during Ga implantation into a wafer). In such case, a carrier gas is used concurrently with the GaI₃ vapor produced by the GaI₃ source. A second cleaning method can be performed after completion of an ion implantation procedure (e.g., after implantation of Ga into a wafer). In such case, a cleaning gas is used, for example, including Ar.

During Ga implantation (normal operation): The exemplary embodiments of the present invention provide for a method to reduce the time it takes to clean ion implanters and to lower contamination of processed semiconductor substrates by reducing buildup of iodine and gallium based residue during ion implantation of Ga using GaI₃ vapor from a solid GaI₃ source by, e.g., using a hydrogen-containing carrier gas or co-gas or co-process gas concurrently with the GaI₃ vapor such that the hydrogen (H) reacts with iodine (I), thus forming volatile hydrogen iodine (HI) molecules that are pumped out by the existing pumping system. In one or more embodiments, during normal operation of the ion implanter 10, Ar/H₂ (argon/hydrogen gas) mixture can be used as the hydrogen-containing carrier gas or co-gas or co-process gas. Ar ions sputter off any contaminants on surfaces resulting in less buildup of residue within the ion source 14 and the analyzer magnet 16. Thus, a carrier gas (e.g., containing H) can be used during normal operation of the ion implanter 10 to clean regions of the ion implanter as Ga ions are being implanted into a wafer.

After Ga implantation: Further, the exemplary embodiments of the present invention include post-cleaning steps for cleaning the ion implanter 10 after Ga implantation has already occurred. The post-cleaning of the ion implanter 10 can be performed by running an Ar-based cleaning gas through the operating ion source 14, through the analyzer magnet 16, and through the remainder of the ion implanter 10 (i.e., the ion beam accelerator column 20, the vertical and horizontal scanning electrodes 22, and the target 26). In one or more embodiments, a Ar/H₂ (argon/hydrogen gas) mixture is used as the Ar-based cleaning gas. After running the Ar ion beam through the ion implanter 10, a hydrogen ion beam can also be run to further aid volatilization of any iodine that may have been left behind.

The extent and exact sequence of the cleaning cycles after Ga implantation can be empirically determined while varying a duration of each ion beam exposure and/or varying target ion beam conditions such as beam energy and beam current, to identify the process conditions producing a desired level of wafer contamination by gallium and/or iodine.

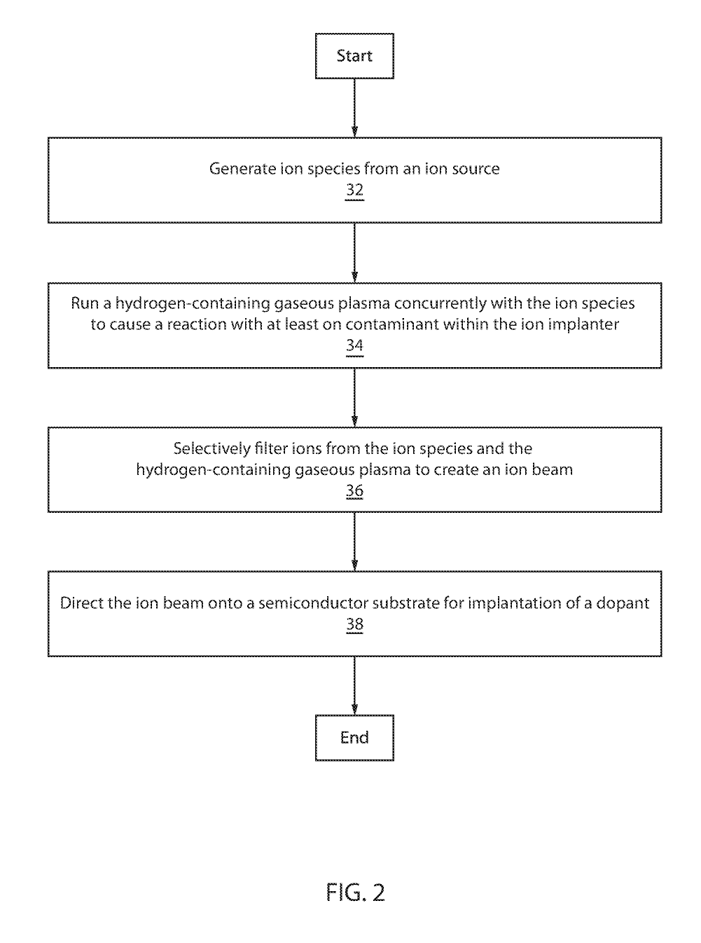

FIG. 2 is a block/flow diagram of an exemplary method for implanting a dopant into a semiconductor substrate, in accordance with an embodiment of the present invention.

At block 32, metallic ion species are generated from an ion source. The ion source can be, e.g., a GaI₃ source. The metallic ion species can then be provided to an analyzer magnet that filters unwanted ions, as described below.

At block 34, a hydrogen-containing gaseous plasma is run concurrently with the metallic ion species to cause a reaction with at least one contaminant within the ion implanter. The at least one contaminant can be iodine (I). The hydrogen-containing gaseous plasma can be e.g., an arsine (AsH₃) based plasma or an argon/hydrogen gas (Ar/H₂) based plasma.

At block 36, ions are selectively filtered from the metallic ion species and the hydrogen-containing gaseous plasma to create an ion beam. The ion beam can be, e.g., a gallium (Ga) ion beam. The ion beam can be deflected and shaped by vertical and horizontal scanning electrodes.

At block 38, the ion beam is directed onto a semiconductor substrate for implantation of a dopant. The dopant can be, e.g., Ga. The semiconductor substrate can be, e.g., Si. Once dopants have been deposited, the wafer can be removed from the ion implanter and another wafer can be inserted therein for dopant implantation.

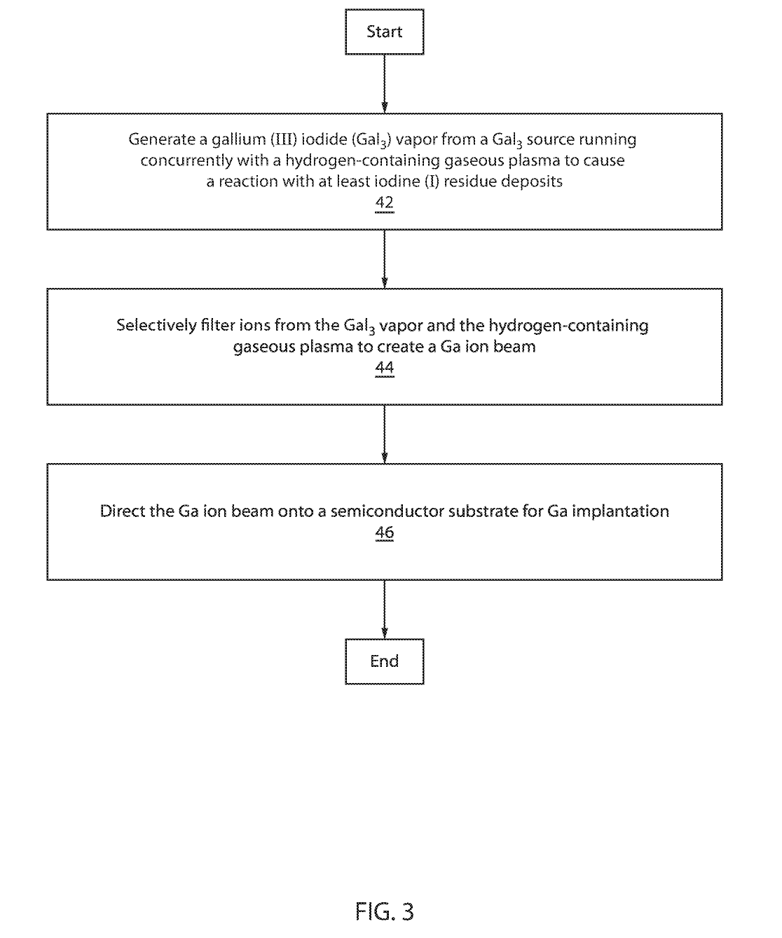

FIG. 3 is a block/flow diagram of an exemplary method for removing gallium (Ga) and iodine (I) contaminants from surfaces of an ion implanter, in accordance with an embodiment of the present invention.

At block 42, a gallium (III) iodide (GaI₃) vapor is generated from a GaI₃ source running concurrently with a hydrogen-containing gaseous plasma to cause a reaction with at least iodine (I) residue deposits. The hydrogen-containing gaseous plasma can be, e.g., an arsine (AsH₃) based plasma or an argon/hydrogen gas (Ar/H₂) based plasma.

At block 44, ions are selectively filtered from the GaI₃ vapor and the hydrogen-containing gaseous plasms to create a Ga ion beam. Of course, any other dopant can be used. For example, boron (B), aluminum (Al), phosphorous (P), arsenic (As), etc.

At block 46, the Ga ion beam is directed onto a semiconductor substrate for Ga implantation. Of course, any other type of dopant implantation can take place. Once dopants have been deposited, the wafer can be removed from the ion implanter and another wafer can be inserted therein for dopant implantation.

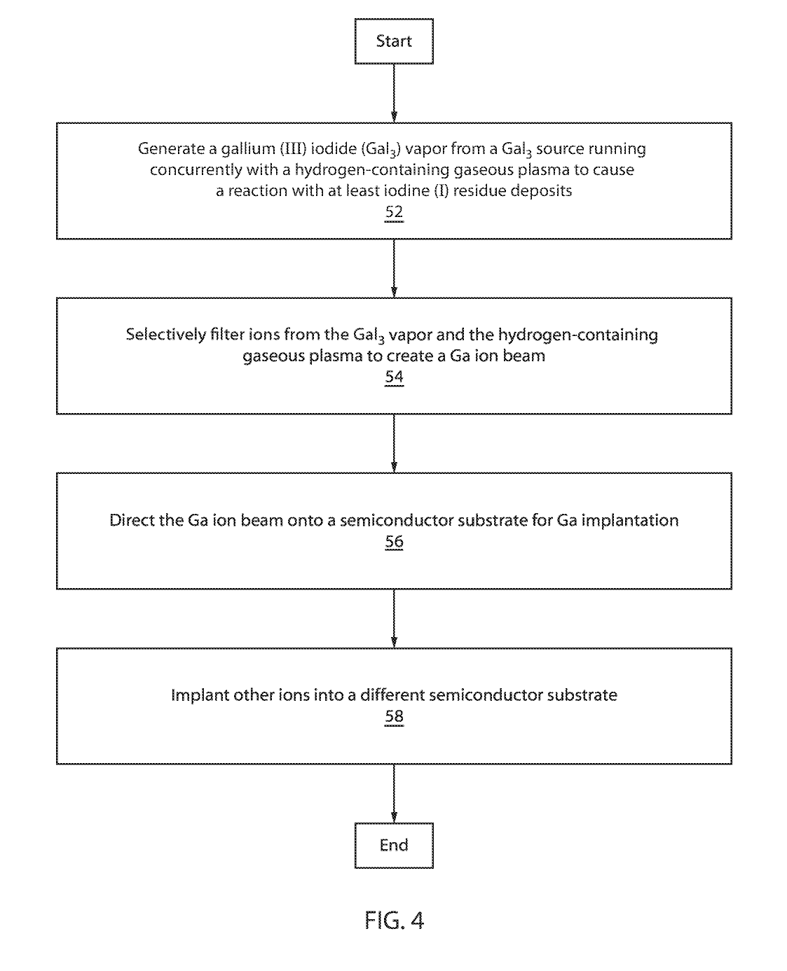

FIG. 4 is a block/flow diagram of an exemplary method for utilizing consecutive ion implantations sequences including implantation of (Ga) ions followed by implantation of different ions, in accordance with an embodiment of the present invention.

At block 52, a gallium (III) iodide (GaI₃) vapor is generated from a GaI₃ source running concurrently with a hydrogen-containing gaseous plasma to cause a reaction with at least iodine (I) residue deposits.

At block 54, ions are selectively filtered from the GaI₃ vapor and the hydrogen-containing gaseous plasms to create a Ga ion beam.

At block 56, the Ga ion beam is directed onto a semiconductor substrate for Ga implantation. Once dopants have been deposited, the wafer can be removed from the ion implanter and another wafer can be inserted therein for dopant implantation.

At block 58, other ions are implanted into a different semiconductor substrate. The other ions can be, e.g., boron (B), phosphorous (P), etc.

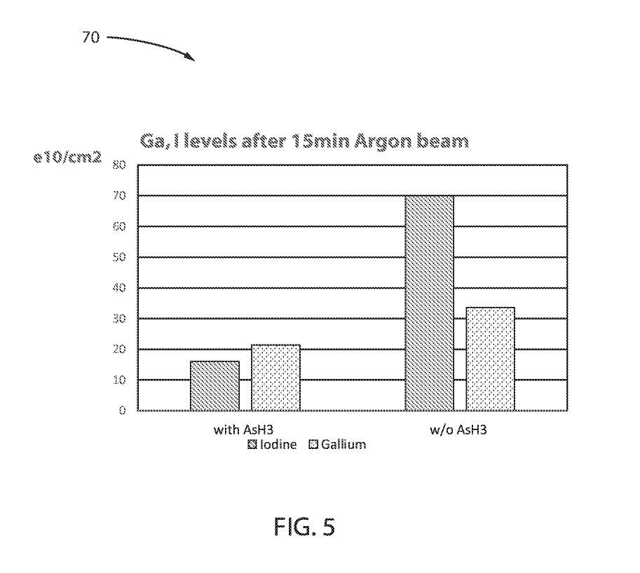

FIG. 5 is an exemplary graph depicting experimental data showing improvement in levels of Ga and I contamination utilizing methods in accordance with an embodiment of the present invention.

The graph 70 depicts the levels of Ga and I in semiconductor wafers processed according to the exemplary method shown in FIG. 4. In this example, the process was split between the conventional approach of using a neutral (argon) carrier gas in the ion source and the present approach of using a hydrogen-containing carrier gas, such as, but not limited to arsine (AsH₃). Multiple semiconductor substrates were implanted with Ga ions at a cumulative Ga dose of about 2.4e¹⁶ ions/cm². Then, pure Ar gas was used in the ion source and an Ar ion beam was run for about 15 minutes through the ion implanter to further reduce any remaining Ga or I contamination. Subsequently, clean semiconductor substrates were implanted with BF₂ (difluoroboron) ions and the level of Ga and I surface contamination were measured in these substrates and depicted in graph 70. The instance of using the hydrogen-containing carrier gas is labeled “with AsH₃” on the left hand side and the instance of using the conventional argon carrier gas is labeled “without AsH₃” on the right hand side. As shown in graph 70, without AsH₃, the levels of Ga and I within the ion implanter are higher than when AsH₃ carrier gas is used (current approach). In fact, the levels of I can be reduced by at least 50% and the levels of Ga can be reduced by at least 25%. This demonstrates the effectiveness of using the hydrogen-containing carrier gas for reducing iodine and gallium contamination. Specifically, this implantation method brings the surface contamination of both Ga and I to below about 2×10¹¹ atoms/cm². Additionally, using an Ar/H₂ gas mixture during normal operation, and sequentially exposing at least the beamline region to argon and hydrogen ion beams, after ion implantation is complete, further reduces contamination levels within the ion implanter 10. Therefore, the ion implanter 10 can be successfully cleaned (i) during normal operation of implanting Ga ions into a wafer by using a carrier gas concurrently with the GaI₃ vapor and (ii) after completion of the Ga implantation (i.e., post-cleaning) by using an argon ion beam and, in certain cases of heavy contamination, a hydrogen ion beam. Thus, there are two different cleaning phases that can be performed at two different operation cycles to clean the ion implanter 10.

The parts of the ion implanter 10 that needs the most maintenance include: the ion source 14, which must be serviced after approximately 100 hours of operation, depending on its operating conditions, the extraction electrodes, and the high voltage insulator, which usually requires cleaning after a few hundred hours of operation. In the ideal case, all feedstock molecules would be ionized and extracted, but in reality a certain amount of feedstock decomposition occurs, which results in the deposition on and contamination of the ion source region. For example, iodine (I) and gallium (Ga) residue readily deposits on surfaces in the ion source region (e.g., with gallium ion implantation with GaI₃ solid source). The residue can form on low voltage insulators in the ion source, causing electrical short circuits, which can interrupt the arc required to produce thermionic electrons. This phenomenon is generally known as “source glitching,” and it is a contributor to ion beam instability, and can eventually cause premature failure of the ion source. The residue can also form on the high voltage components of the ion implanter 10, such as the source insulator or the surfaces of the extraction electrodes, thus causing energetic high voltage sparking. Such sparks are another contributor to beam instability, and the energy released by these sparks can damage sensitive electronic components, leading to increased equipment failures and poor mean time between failures (MTBF).

In addition to the operational difficulties caused by residues in the ion implanter 10, there are also significant personnel safety issues due to the emission of toxic or corrosive vapors when components are removed for cleaning. The safety issues arise wherever residues are present, but are of particular concern in the ion source region because the ion source 14 is the most frequently maintained component of the ion implanter 10. To minimize down time, contaminated ion sources are often removed from the implanter at temperatures significantly above room temperature, which increases the emission of vapors and exacerbates the safety issue.

Thus, in view thereof, the exemplary embodiments of the present invention provide for a method to reduce buildup of iodine and gallium based residue during ion implantation of Ga using GaI₃ vapor from a solid GaI₃ source (i.e., normal operation) by using, e.g., an Ar/H₂ mixture as the carrier gas or co-gas or co-process gas along with the GaI₃ vapor such that the hydrogen getters the iodine to form volatile HI and Ar sputters off Ga and any contaminants on surfaces resulting in less build up. Implantation of Ga from GaI₃ source using H containing carrier gas or co-gas or co-process gas (e.g., arsine or Ar/H₂ mixture) enables preventive removal of Ga and I residue within the ion source.

The exemplary embodiments of the present invention further provide for a method including the use of, e.g., Ar/H₂ plasma exposure as a post cleaning method for removing iodine and gallium containing residues from implant chamber surfaces following a Ga implant using GaI₃. Stated differently, the exemplary embodiments of the present invention provide for cleaning gallium (Ga) and iodine (I) from the ion implanter following use of GaI₃ to implant Ga without the need for gettering with dedicated wafers.

The embodiments described herein can be added directly to newly manufactured ion implantation tools or in the alternative, implanters already in use can be easily retrofitted with the cleaning systems described herein.

The method and apparatus taught herein is used to at least partially remove the residue from the components of the ion implanter and prevent excessive buildup of such residue, and to do so in such a manner that residue is removed selectively with respect to the materials from which the components of the ion implanter are constructed, e.g., aluminum, tungsten, etc. As used herein, the term “at least partially remove” is defined as the removal of at least about 25%, more preferably at least about 50%, and most preferably at least about 75% of the residue to be removed.

The advantages of the present invention include, but are not limited to, selective cleaning of unwanted residue in at least the ion source region of an ion implantation system. Residue removal from the ion source region using the methods introduced herein reduces source glitching and extraction arcing, thereby contributing to more stable operation of the ion implanter. Further, the ion source lifetime and MTBF (mean time between failures) are increased, with a concomitant decrease in preventative maintenance costs and time.

In situ cleaning of the ion source region should be performed after each Ga implantation sequence, i.e., after implanting a cassette of semiconductor wafers, although the frequency and duration of cleanings can be more or less often depending on the cumulative dose of implanted Ga ion between cleans. The length of the cleaning operation can be less than about 15 minutes, although the cleaning time can be more or less depending on desired level of Ga or I contamination after the cleaning.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which can include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers may also be present.

It will be understood that, although the terms first, second, etc. can be used herein to describe various elements, these elements should not be limited by these terms. These terms are only used to distinguish one element from another element. Thus, a first element could be termed a second element without departing from the scope of the present concept.

Having described preferred embodiments of a method for gallium (Ga) implantation cleaning, it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1-18. (canceled)

19. A system for cleaning an ion implanter during operation of the ion implanter, the system comprising:
an ion source for generating metallic ion species, the ion source run concurrently with a hydrogen-containing gaseous plasma to cause a reaction with at least one contaminant within the ion implanter; and
a filter for selectively filtering ions from the metallic ion species and the hydrogen-containing gaseous plasma to create an ion beam;
wherein the ion beam is directed onto a semiconductor substrate for implantation of a dopant.

20. The system of claim 19, wherein the at least one contaminant is iodine (I) and the dopant is gallium (Ga).
